(19) United States
(12) Patent Application Publication
(10) Pub. No.: US 2022/0063987 A1
(43) Pub. Date: Mar. 3, 2022

(54) MEMS PACKAGING STRUCTURE AND FABRICATION METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Ningbo, Zhejiang (CN)

(21) Appl. No.: 17/419,113

(22) PCT Filed: Nov. 5, 2019
(86) PCT No.: PCT/CN2019/115615

§ 371 Date: Jun. 28, 2021

(30) Foreign Application Priority Data
Dec. 27, 2018 (CN) 201811614185.X

(51) Int. Cl. B81B 7/00; B81C 1/00

(52) U.S. Cl. CPC B81B 7/007; B81C 1/00301; B81B 2201/0228; B81B 2201/0235; B81C 2203/0792; B81B 2201/0264; B81B 2201/03; B81B 2207/012; B81B 2207/07; B81B 2201/0242

(57) ABSTRACT

A micro-electro-mechanical system (MEMS) package structure and a method for fabricating the MEMS package structure. The MEMS package structure includes a MEMS die (210,220) and a device wafer (100). The MEMS die (210,220) is arranged on a first surface (100a) of the device wafer and includes a closed micro-cavity (211,221) and a contact pad (212,222) configured to be coupled to an external electrical signal. In the device wafer (100), there are arranged a control unit and an interconnection structure (300) electrically connected to each of the contact pad (212,222) and the control unit. On a second surface (100b) of the device wafer, there is arranged a rewiring layer (400) electrically connected to the interconnection structure (300). According to the MEMS package structure fabrication method, arranging the MEMS die (210,220) and the rewiring layer (400) on opposing sides of the device wafer (100) is conducive to shrinkage of the MEMS package structure. In addition, the MEMS package structure allows the integration of a plurality of MEMS dies of the same or different structures and functions on the same device wafer.

### TECHNICAL FIELD

The present invention relates to the field of semiconductor technology and, in particular, to a micro-electro-mechanical system (MEMS) package structure and a method for fabricating it.

### BACKGROUND

The development of very-large-scale integration (VLSI) is leading to increasing shrinkage of critical dimensions of integrated circuits, imposing more and more stringent requirements on integrated circuit packaging techniques. In the market for MEMS sensor package structures, MEMS dies have been widely used in smart phones, fitness wristbands, printers, automobiles, drones, head-mounted VR/AR devices and many other products. Common MEMS dies include, among others, those for pressure sensors, accelerometers, gyroscopes, MEMS microphones, optical sensors and catalytic sensors. A MEMS die is usually integrated with another die using a system in package structure (SiP) approach to form a MEMS device. Specifically, the MEMS die is usually fabricated on one wafer and integrated with an associated control circuit that is formed on another wafer. Currently, the integration is usually accomplished by either of the following two methods: separately bonding the MEMS die-containing wafer and the control circuit-containing wafer to a single packaging substrate and electrically connecting the MEMS die and the control circuit to solder pads on the substrate through wiring so that the control circuit is electrically connected to the MEMS die; and directly bonding the MEMS die-containing wafer to the control circuit-containing wafer with their corresponding pads electrically connected, so as to achieve an electrical connection between the control circuit and the MEMS die.

However, the above first integration method requires reserved areas for the solder pads, which are often large and thus unfavorable to miniaturization of the resulting MEMS device. MEMS dies with different functions (or structures) are generally fabricated with different processes, and it is usually only possible to fabricate MEMS dies of the same function (or structure) on a single wafer. Therefore, for the above latter integration method, it is difficult to form MEMS dies of different functions on a single wafer using semiconductor processes, and it will be complicated in process, costly and bulky in size of the resulting MEMS device to separately bond wafers containing MEMS dies of different functions to wafers containing respective control circuits and then interconnect them together. Thus, the current integration methods for MEMS dies and the resulting MEMS package structures still fall short in meeting the requirements of practical applications in terms of size and function integration ability.

### SUMMARY OF THE INVENTION

It is an object of the present invention to provide a MEMS package structure with a reduced size and a method for fabricating such a package structure. It is another object of the present invention to provide a MEMS package structure with enhanced function integration ability.

In one aspect of the present invention, there is provided a MEMS package structure comprising:

a MEMS die comprising a closed micro-cavity and a contact pad configured to be coupled to an external electrical signal; a device wafer having a first surface and a second surface opposite to the first surface, wherein the MEMS die is bonded to the first surface and a control unit associated with the MEMS die is arranged in the device wafer; an interconnection structure arranged in the device wafer, the interconnection structure electrically connected to each of the contact pad and the control unit; and a rewiring layer arranged on the second surface, the rewiring layer electrically connected to the interconnection structure.

Optionally, a plurality of MEMS dies may be arranged on the first surface, which are categorized in the same or different types depending on a fabrication process thereof.

Optionally, a plurality of MEMS dies may be arranged on the first surface, and the plurality of MEMS are categorized in the same or different types depending on vacuum levels of corresponding micro-cavities.

Optionally, a plurality of MEMS dies may be arranged on the first surface, which include at least one of: a gyroscope, an accelerometer, an inertial sensor, a pressure sensor, a displacement sensor and a micro-actuator.

Optionally, the control unit may comprise one or more MOS transistors.

Optionally, the interconnection structure may comprise:

a first conductive plug and a second conductive plug, wherein: the first conductive plug extends through at least a part of the device wafer and electrically connected to the control unit; and the second conductive plug extends through the device wafer and electrically connected to the contact pad, wherein the rewiring layer is electrically connected to each of the first and second conductive plugs.

Optionally, an isolation structure may be arranged in the device wafer and located between adjacent MOS transistors, wherein each of the first and second conductive plugs extends through corresponding isolation structure.

Optionally, the MEMS package structure may further comprise:

a bonding layer covering the first surface, wherein the MEMS die is bonded to the first surface by the bonding layer; and an encapsulation layer covering the MEMS die and the bonding layer.

Optionally, the bonding layer may comprise an adhesive material.

Optionally, the adhesive material may comprise a dry film.

Optionally, the micro-cavity may be filled with a damping gas or is vacuumed.

Optionally, the rewiring layer may comprise a rewiring connection and a solder pad electrically connected to the rewiring connection.

In another aspect of the present invention, there is provided a method for fabricating a MEMS package structure, comprising:

providing a MEMS die and a device wafer for control of the MEMS die, wherein the MEMS die comprises a closed micro-cavity and a contact pad configured to be coupled to an external electrical signal, the device wafer having a first surface, wherein a control unit is formed in the device wafer; bonding the MEMS die to the first surface; forming an interconnection structure in the device wafer, the interconnection structure electrically connected to each of the contact pad and the control unit; and forming a rewiring layer on a surface of the device wafer opposing the first surface, the rewiring layer electrically connected to the interconnection structure.

Optionally, bonding the MEMS die to the first surface may comprise:

forming a bonding layer to bond the MEMS die to the first surface; and forming an encapsulation layer to cover the MEMS die and the bonding layer.

Optionally, forming the interconnection structure in the device wafer may comprise:

forming a first conductive plug and a second conductive plug in the device wafer, wherein: the first conductive plug extends through at least a part of the device wafer and electrically connected to the control unit; and the second conductive plug extends through the device wafer and electrically connected to the contact pad, each of the first and second conductive plugs having one end exposed at the surface of the device wafer opposing the first surface.

Optionally, the method may further comprise, prior to the formation of the interconnection structure in the device wafer,

grinding the device wafer along the thickness direction thereof from a side of the device wafer opposing the first surface.

### BRIEF DESCRIPTION OF THE DRAWINGS

FIG. 1 is a schematic cross-sectional view showing a device wafer and a plurality of MEMS dies provided in a method of fabricating a MEMS package structure in accordance with an embodiment of the present invention.

FIG. 2 is a schematic cross-sectional view showing a structure resulting from bonding the plurality of MEMS dies to the device wafer using a bonding layer in the method of fabricating a MEMS package structure in accordance with an embodiment of the present invention.

FIG. 3 is a schematic cross-sectional view showing a structure resulting from the formation of an encapsulation layer in a method of fabricating a MEMS package structure in accordance with an embodiment of the present invention.

FIG. 4 is a schematic cross-sectional view showing a structure resulting from the grinding of the substrate in a method of fabricating a MEMS package structure in accordance with an embodiment of the present invention.

FIG. 5 is a schematic cross-sectional view showing a structure resulting from the formation of interconnection structures in a method of fabricating a MEMS package structure in accordance with an embodiment of the present invention.

FIG. 6 is a schematic cross-sectional view showing a structure resulting from the formation of rewiring layers in a method of fabricating a MEMS package structure in accordance with an embodiment of the present invention.

In these figures,

100: a device wafer; 100a: a first surface; 100b: a second surface; 101: a substrate; 102: an isolation structure; 103: a first dielectric layer; 104: a second dielectric layer; 210: a first MEMS die; 211: a first micro-cavity; 212: a first contact pad; 220: a second MEMS die; 221: a second micro-cavity; 222: a second contact pad; 300: an interconnection structure; 310: a first conductive plug; 320: a second conductive plug; 400: a rewiring layer; 500: a bonding layer; and 501: an encapsulation layer.

### DETAILED DESCRIPTION

The present invention will be described below in greater detail by way of particular embodiments with reference to the accompanying drawings. Features and advantages of the invention will be more apparent from the following description. Note that the accompanying drawings are provided in a very simplified form not necessarily drawn to exact scale, and their only intention is to facilitate convenience and clarity in explaining the disclosed embodiments.

In the following, the terms “first”, “second”, and so on may be used to distinguish between similar elements without necessarily implying any particular ordinal or chronological sequence. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Identical components or features may be shown in different accompanying drawings, and not all such components and features are labeled in each drawing for the sake of visual clarity, even if they are readily identifiable in all the drawings.

Referring to FIG. 6, a micro-electro-mechanical system (MEMS) package structure according to an embodiment of the present invention includes a MEMS die (e.g., the first MEMS die 210 and/or second MEMS die 220 of FIG. 6) and device wafer 100. The MEMS die includes a closed micro-cavity and a contact pad configured to be coupled to an external electrical signal (e.g., as FIG. 6 shows, the first MEMS die 210 includes a first micro-cavity 211 and a first contact pad 212, and the second MEMS die 220 includes a second micro-cavity 221 and a second contact pad 222). The device wafer 100 has a first surface 100a and a second surface 100b opposing the first surface 100a and contains, formed therein, a control unit and interconnection structure 300, which are associated with the MEMS die. The interconnection structure 300 is electrically connected to each of the contact pad of the MEMS die and the control unit in the device wafer. Further, a rewiring layer 400 is formed on the second surface 100b of the device wafer 100, the rewiring layer 400 is electrically connected to the interconnection structure 300.

The MEMS package structure may include a plurality of said MEMS dies, the device wafer 100 is used to control the plurality of MEMS dies, a plurality of control units corresponding to the plurality of MEMS dies 200 are arranged in the device wafer so as to respectively drive the operation of the plurality of MEMS dies, wherein the plurality of MEMS dies are bonded to the first surface 100a of the device wafer. The device wafer 100 may be formed using a general-purpose semiconductor process. For example, the plurality of control units may be formed in a substrate (e.g., silicon substrate) to result in the formation of the device wafer 100.

Specifically, as shown in FIG. 6, in this embodiment, the device wafer 100 may include a substrate 101. The substrate 101 may be, among others, a silicon substrate or a silicon-on-insulator (SOI) substrate. Examples of materials from which the substrate 101 can be fabricated may also include germanium, silicon germanium, silicon carbide, gallium arsenide, indium gallium and other Group III and V compounds. Preferably, the substrate 101 is selected as a substrate allowing relatively easy semiconductor processing or integration. The plurality of control units may be formed on the basis of the substrate 101.

Each control unit may include one or more MOS transistors, and in the latter case, adjacent said MOS transistors may be isolated from one another by isolation structure(s) 102 formed in the device wafer 100 (or in the substrate 101) and by an insulating material deposited on the substrate 101. Each isolation structure 102 may be, for example, a shallow trench isolation (STI) and/or deep trench isolation (DTI) structure. As an example, the control unit may control the MEMS die by a control electrical signal output from a source/drain of one of the MOS transistor(s). In this embodiment, the device wafer 100 further comprises a first dielectric layer 103 formed on one of the surfaces of the substrate 101, and the source/drain of the control unit for outputting a control electrical signal (i.e., serving as an electrical connection terminal) is arranged in the first dielectric layer 103. On the other surface of the substrate 101, a second dielectric layer 104 is formed. Each of the first and second dielectric layers 103, 104 may be formed of at least one material selected from insulating materials including silicon oxide, silicon nitride, silicon carbide and silicon oxynitride.

For convenience, the surface of the first dielectric layer 103 away from the substrate 101 may be taken as the first surface 100a of the device wafer 100, and the surface of the second dielectric layer 104 away from the substrate 101 as the second surface 100b of the device wafer 100. The substrate 101 is preferably a thin substrate, which allows the MEMS package structure to have a reduced thickness.

In order to establish an electrical connection between the MEMS die and the control unit in the device wafer, in this embodiment, the interconnection structure 300 is provided in the device wafer 100, which is electrically connected to both the contact pad in the MEMS die and the control unit in the device wafer 100. Specifically, referring to FIG. 6, the interconnection structure 300 may include a first conductive plug 310 and a second conductive plug 320. The first conductive plug 310 may extend through at least part of the device wafer 100 and come into electrical connection with the control unit. The second conductive plug 320 may extend through the device wafer 100 and come into electrical connection with the contact pad in the MEMS die. Preferably, each of the first and second conductive plugs 310, 320 extends through an isolation structure 102 in order to not or less adversely affect the control unit in the device wafer 100.

In case of a plurality of MEMS dies being integrated, they may be of the same or different functions, uses or structures. MEMS dies for various MEMS devices such as gyroscopes, accelerometers, inertial sensors, pressure sensors, displacement sensors and micro-actuators (e.g., micro-motors, micro-resonators, micro-relays, micro-optical/RF switches, optical projection displays, flexible skins, micro-pump/valves) can be fabricated on separate substrates (e.g., silicon wafers) using MEMS die fabrication processes well known in the art and then diced into individual MEMS dies. Any of such MEMS dies may be used in this embodiment. In practical implementations, depending on the design requirements or the intended use, a number or plurality of MEMS dies of different types may be selected and arranged on the first surface 100a of the device wafer 100. For example, MEMS dies of the same or different sensing functions may be bonded to the first surface 100a of the device wafer 100. It is to be understood that while the description of this embodiment focuses on the MEMS package structure comprising the device wafer 100 and the MEMS dies arranged on its first surface 100a, however, it does not imply that the MEMS package structure of the present embodiment is only made up of these components because the device wafer 100 may be further provided with one or more different chips arranged thereon or bonded thereto (e.g., memory chips, communication chips, processor chips, etc.), one or more different devices arranged thereon (e.g., power devices, bipolar devices, resistors, capacitors, etc.) and/or components and connection well known in the art. The present invention is not limited to only one MEMS die being bonded to the device wafer 100, as two, three or more MEMS dies can be bonded thereto. In the latter case, structures and/or types of the plurality of MEMS dies may vary depending on the actual requirements.

Different MEMS dies may be categorized in the same or different types depending on how they are fabricated. In this embodiment, in order to demonstrate improved function integration ability of the MEMS package structure of the present invention, the plurality of MEMS dies are preferred to be fabricated using fabricating processes that are not completely the same. Different MEMS dies may also be categorized in the same or different types depending on vacuum levels of their micro-cavities. In another embodiment, for example, a ratio of vacuum levels of micro-cavities of two corresponding MEMS dies may be greater than or equal to 10. In a further embodiment, the plurality of the MEMS dies may include at least one of: a gyroscope, an accelerometer, an inertial sensor, a pressure sensor, a displacement sensor and a micro-actuator. As required, the micro-cavity of each MEMS die may be either vacuumed or filled with a damping gas. In the scenario of FIG. 6, the first MEMS die 210 is, for example, for a gyroscope, while the second MEMS die 220 is, for example, for an accelerometer.

In this embodiment, the MEMS package structure may further include a bonding layer 500 that bonds the MEMS die(s) (e.g., the first MEMS die 210 and/or second MEMS die 220) to the device wafer 100. The bonding layer 500 may cover the first surface 100a of the device wafer 100, and each MEMS die may be bonded to the first surface 100a of the device wafer 100 by the bonding layer 500.

Examples of suitable materials for the bonding layer 500 may include oxides or other materials. For example, the bonding layer 500 may be a bonding material that bonds each MEMS die to the first surface 100a of the device wafer 100 by fusing bonding, vacuum bonding or otherwise. Examples of suitable materials for the bonding layer 500 may also include adhesive materials. In this case, for example, the bonding layer 500 may be a die attach film (DAF) or a dry film, which glues the MEMS die(s) to the device wafer 100 by adhesion. In the latter case, the dry film may be an adhesive photoresist film where a polymerization reaction can take place in the presence of ultraviolet radiation and produce a stable substance that adheres to a surface to be bonded. The dry film may cover the first surface 100a or part thereof, and provides the advantages of electroplating and etching resistance. In order for easy interconnection to be achieved on the side of the second surface 100b, each MEMS die is preferably bonded in an orientation with the contact pad facing a bonding surface of the device wafer 100. In this embodiment, the first surface 100a of the device wafer 100 is taken as the bonding surface. In alternative embodiments, it is also possible to take the second surface 100b as the bonding surface.

In this embodiment, the MEMS package structure may further include an encapsulation layer 501, which covers each MEMS die bonded to the device wafer 100 as well as the aforementioned bonding layer 500. The encapsulation layer 501 may be provided on the side of the first surface 100a of the device wafer 100 in order to more firmly fix each MEMS die to the device wafer 100 and protect it from external damage. The encapsulation layer 501 may be formed of, for example, a plastic material. For example, an injection molding process may be employed to fill gap(s) between the MEMS die(s) with the plastic material and fix each MEMS die to the bonding layer 500. The plastic material of the encapsulation layer 501 may be in a softened or flowable form during the molding and may be molded in a predetermined shape. Alternatively, the material of the encapsulation layer 501 may solidify by chemical crosslinking. As an example, the material of the encapsulation layer 501 may include, for example, at least one of thermosetting resins including phenolic resins, urea-formaldehyde resins, formaldehyde-based resins, epoxy resins, polyurethanes and so on. Preferably, the material of the encapsulation layer 501 is selected as an epoxy resin, in which a filler may be added, as well as one or more of various additives (e.g., curing agents, modifiers, mold release agents, thermal color agents, flame retardants, etc.) For example, a phenolic resin may be added as a curing agent and a solid particle (e.g.,silica powder) as a filler.

In this embodiment, the MEMS package structure may further include a rewiring layer 400 arranged on the second surface 100b of the device wafer 100. The rewiring layer 400 may be made of a conductive material so as to be electrically connected to the interconnection structure 300. In particular, as shown in FIG. 6, the rewiring layer 400 may cover part of each of the first and second conductive plugs 310, 320 and thus come into electrical connection with the interconnection structure 300.

Preferably, the rewiring layer 400 may include a rewiring connection and a solder pad (I/O pad) (not shown) electrically connected to the rewiring connection. The solder pad may be configured to be coupled to an external signal or device so as to process and control the electrical signal received from the rewiring connection.

The MEMS package structure allows integration of the MEMS die with the device wafer 100 with a reduced overall package structure size achieved by arranging the rewiring layer 400 on the side opposite to the bonding side. Moreover, the rewiring layer 400 may include a rewiring connection and a solder pad electrically connected to the rewiring connection. Arranging the solder pad on the second surface 100b can result in an additional reduction in the package structure size. Further, the MEMS package structure is also improved in terms of function integration ability because a plurality of MEMS dies of the same or different functions (uses) and structures are allowed to be integrated on the same device wafer 100.

In embodiments of the present invention, there is provided a method for fabricating a MEMS package structure as defined above. Steps for fabricating the MEMS package structure are as follows:

step 1: providn a MEMS die and a device wafer for control of the MEMS die. The MEMS die includes a closed micro-cavity and a contact pad for being coupled to an external electrical signal. The device wafer has a first surface, and a control unit is formed in the device wafer.

step 2: bonding the MEMS die to the first surface.

step 3: forming an interconnection structure in the device wafer, which is electrically connected to each of the contact pad and the control unit.

step 4: forming a rewiring layer, which is electrically connected to the interconnection structure, on the surface of the device wafer opposite to the first surface.

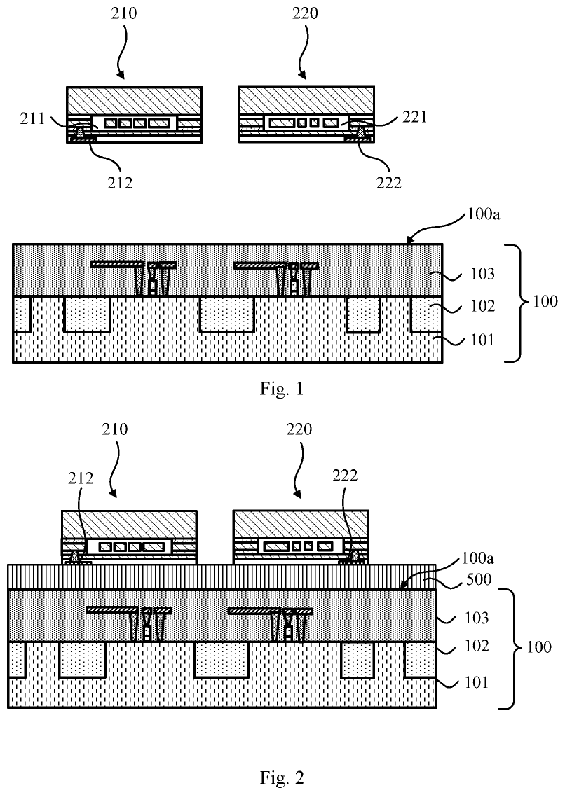

A more detailed process for fabricating a MEMS package structure in accordance with embodiments of the present invention will be described with reference to FIGS. 1 to 6.

FIG. 1 is a schematic cross-sectional view showing a device wafer and a plurality of MEMS dies provided in a method for fabricating a MEMS package structure in accordance with an embodiment of the present invention. Referring to FIG. 1, in a first step, the MEMS dies and the device wafer 100 for control of the MEMS dies are provided. the MEMS dies include a closed micro-cavity and a contact pad for being coupled to an external electrical signal. The device wafer 100 has a first surface 100a, and control units are formed in the device wafer 100. In this embodiment, instead of only one MEMS die, two or more MEMS dies may be integrated on the device wafer 100, and two or more associated control units may be accordingly formed in the device wafer 100. The device wafer 100 is generally in the form of a flat plate, and the plurality of control units may be arranged therein side by side.

In this embodiment, the device wafer 100 may include a substrate 101, which is a silicon substrate or silicon-on-insulator (SOI) substrate, for example. The plurality of control units may be formed on the basis of the substrate 101 using an established semiconductor process in order to subsequently control the respective MEMS dies. Each control unit may consist of a set of CMOS control circuits. For example, each control unit may include one or more MOS transistors, and in the latter case, adjacent said MOS transistors may be isolated from one another by isolation structure(s) 102 formed in the substrate 101 (or in the device wafer 100) and by an insulating material deposited on the substrate 101. Each isolation structure 102 may be, for example, a shallow trench isolation (STI) and/or deep trench isolation (DTI) structure. The device wafer 100 may further include a first dielectric layer 103 formed on one surface of the substrate 101, and a connection terminal of each control unit for outputting a control electrical signal may be arranged in the first dielectric layer 103. For convenience, the surface of the first dielectric layer 103 away from the substrate 101 may be taken as the first surface 100a of the device wafer 100. The device wafer 100 may be fabricated using a method known in the art.

The plurality of MEMS dies may be of the same or different functions, uses or structures. In this embodiment, in order for the MEMS package structure to be versatile or multi-functional, the MEMS dies to be integrated are preferably of two or more different types. For example, the MEMS dies 200 may be at least two selected from those for a gyroscope, an accelerometer, an inertial sensor, a pressure sensor, a flow sensor, a displacement sensor and a micro-actuator, or from those for an electric field sensor, an electric field strength sensor, a current sensor, a magnetic flux sensor and a magnetic field strength sensor. In this embodiment, each MEMS die may be an independent chip (or die) with a closed micro-cavity serving as a sensing component and a contact pad for receiving an external electrical signal (for controlling operation of the MEMS die). The micro-cavity may be either a high- or low-vacuum environment or filled with a damping gas.

Referring to FIG. 1, as an example, the plurality of MEMS die include a first MEMS die 210 and a second MEMS die 220. The first MEMS die 210 is, for example, for a gyroscope, while the second MEMS die 220 is, for example, for an accelerometer. It could be appreciated that, although only two MEMS dies are shown in FIG. 1, it is also possible that the MEMS package structure in this embodiment contains one or more than two MEMS dies.

Specifically, the first MEMS die 210 may include a first micro-cavity 211 serving as a sensing component and a first contact pad 212 for receiving an external electrical signal. The second MEMS die 220 may include a second micro-cavity 221 serving as a sensing component and a second contact pad 222 for receiving an external electrical signal. Each of the first and second pads 212, 222 may be exposed at a surface of the respective MEMS die. Each of the MEMS die may be fabricated using a method known in the art.

FIG. 2 is a schematic cross-sectional view showing a structure resulting from bonding the plurality of MEMS dies to the device wafer using a bonding layer in the method for fabricating the MEMS package structure in accordance with an embodiment of the present invention. Referring to FIG. 2, in a second step, the MEMS dies are bonded to the first surface 100a of the device wafer 100. In case of a plurality of MEMS dies to be integrated, they may be arranged side by side on the first surface 100a.

Specifically, a bonding layer 500 may be formed on the first surface 100a of the device wafer 100, by which the MEMS dies are bonded to the bonding layer 500. In this embodiment, the bonding layer 500 may cover the first surface 100a of the device wafer 100.

In one embodiment, the bonding of the MEMS dies to the device wafer 100 may be accomplished with, for example, a fusing bonding process or vacuum bonding process. In this case, the bonding layer 500 may be formed of a bonding material (e.g., silicon oxide). In another embodiment, the bonding of the MEMS dies to the device wafer 100 may be accomplished by both a bonding process and a light (or thermal) curing process. In this case, the bonding layer 500 may include an adhesive material, in particular, a die attach film or a dry film. The plurality of MEMS dies may be bonded one by one, or a part or whole thereof first transferred to a carrier plate and then bonded onto the device wafer 100 at the same time or in batches. In order for easy interconnection and rewiring to be achieved on the side of the device wafer 100 away from the bonding surface (in this embodiment, for example, the first surface 100a), each MEMS die is preferably bonded in an orientation with the contact pad facing the bonding surface of the device wafer 100.

In order to protect the MEMS dies on the device wafer 100 from external factors (e.g., moisture, oxygen, shock, electroplating etc.) and fix them more firmly, in this embodiment, before the third step is carried out, the method may further include forming an encapsulation layer on the side of the first surface 100a of the device wafer 100.

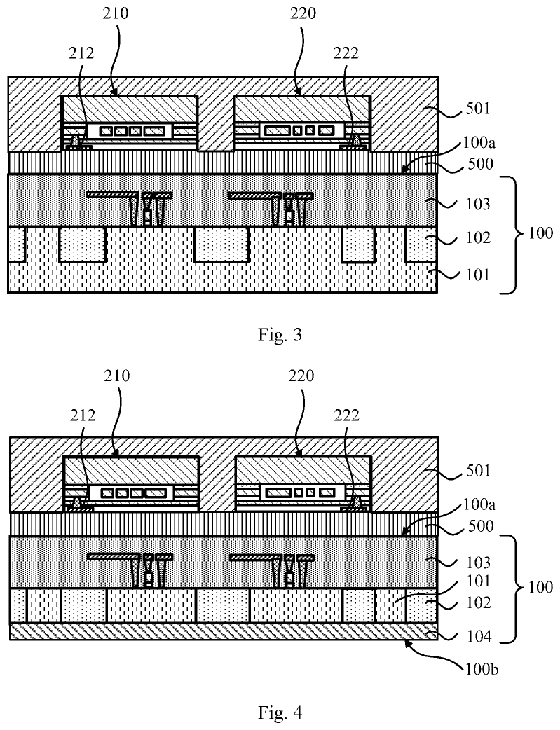

FIG. 3 is a schematic cross-sectional view showing a structure resulting from the formation of the encapsulation layer in the method for fabricating the MEMS package structure in accordance with an embodiment of the present invention. Referring to FIG. 3, subsequent to the bonding of the MEMS dies to the first surface 100a of the device wafer 100 by the bonding layer 500, the encapsulation layer 501 is formed on the device wafer 100. The encapsulation layer 501 may cover both the MEMS dies and the bonding layer 500. Examples of suitable materials for the encapsulation layer 501 may include: inorganic insulating materials, such as silicon oxide, silicon nitride, silicon carbide, silicon oxynitride, etc.; thermoplastic resins, such as polycarbonate, polyethylene terephthalate, polyethersulfone, polyphenylether, polyamides, polyetherimides, methacrylic resins, cyclic polyolefin based resins, etc.; thermosetting resins, such as epoxy resins, phenolic resins, urea-formaldehyde resins, formaldehyde-based resins, polyurethanes, acrylic resins, vinyl ester resins, imide based resins, urea resins, melamine resins, etc.; and organic insulating materials, such as polystyrene, polyacrylonitrile, etc. The encapsulation layer 501 may be formed using, for example, a chemical vapor deposition process or an injection molding process. Preferably, the formation of the encapsulation layer 501 further involves a planarization process performed on the side of the device wafer 100 with the bonding layer 500, which results in a flat top surface of the encapsulation layer 501 (e.g., parallel to the first surface 100a) capable of serving as a support surface in the subsequent interconnection and rewiring steps.

FIG. 4 is a schematic cross-sectional view showing a structure resulting from the grinding of the device wafer in the method for fabricating the MEMS package structure in accordance with an embodiment of the present invention. In order for the MEMS package structure being fabricated to have a reduced size, before the third steps is carried out, in this embodiment, the method may further include grinding the device wafer 100 along a direction of thickness thereof from the side opposite to the first surface 100a.

The grinding of the device wafer 100 may be accomplished with a back-grinding process, a wet etching process or a hydrogen ion implantation process. In this embodiment, the substrate 101 may be grinded from the side thereof opposing the first surface 100a until it becomes flush with bottom surfaces of the isolation structures 102 in the substrate 101.

In order to optimize the grinded surface with enhanced adhesion of the subsequently formed rewiring layers and reduced surface defects, subsequent to the grinding of the substrate 101, a dielectric material may be deposited onto the thinned surface of the device wafer 100, thus resulting in the formation of a second dielectric layer 104, as shown in FIG. 4. The resulting second dielectric layer 104 may cover the grinded surface of the device wafer 100. For convenience, the surface of the second dielectric layer 104 away from the first surface 100a of the device wafer 100 can be considered as the second surface 100b of the device wafer 100.

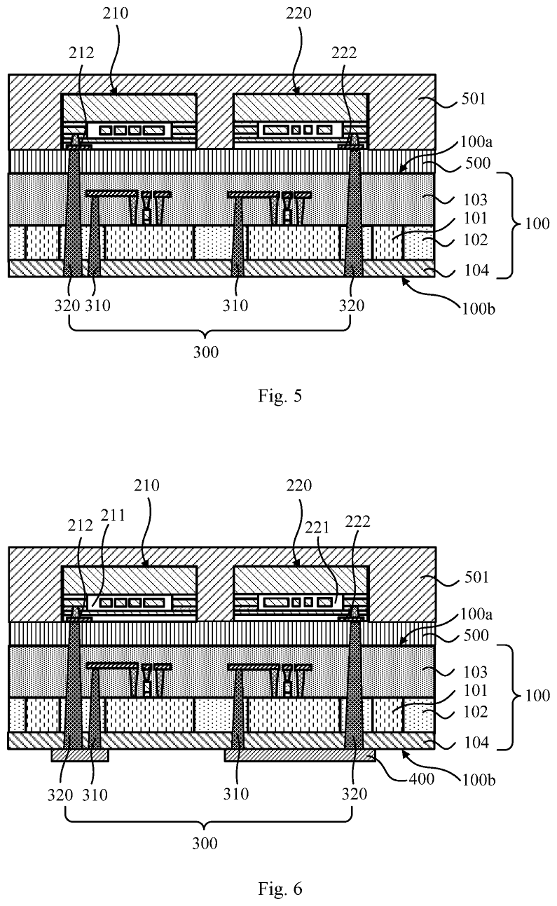

FIG. 5 is a schematic cross-sectional view showing a structure resulting from the formation of interconnection structures in the method for fabricating the MEMS package structure in accordance with an embodiment of the present invention. Referring to FIG. 5, in the third step, interconnection structures 300 electrically connected to the contact pads and the control units are formed in the device wafer 100. It is to be understood that although the device wafer 100 is shown in a non-flipped configuration throughout the figures in order to better demonstrate the correspondence of the illustrated structures to the described steps, in this embodiment, the device wafer 100 may be flipped over in the third and fourth steps with the surface of the encapsulation layer 501 away from the first surface 100a as a support surface.

Each interconnection structure 300 may include two or more electrical contacts, electrical connection members and electrical connection lines each connecting any two of the above, which are all formed in the device wafer 100. In this embodiment, each second interconnection element 320 includes a first conductive plug 310 and a second conductive plug 320 both formed in the device wafer 100. In case of a plurality of MEMS dies being integrated, a plurality of said first conductive plugs 310 and a plurality of said second conductive plugs 320 may be formed. Each first conductive plug 310 extends through at least part of the device wafer 100 and comes into electrical connection with a respective one of the control units, and each second conductive plug 320 extends through the device wafer 100 and comes into electrical connection with the contact pad of a respective one of the MEMS dies. Each of the first and second conductive plugs 310, 320 is exposed at one end at the surface of the device wafer 100 opposite to the first surface 100a (e.g., the second surface 100b in FIG. 5). In this way, the interconnection structures 300 are electrically connected both to the contact pads in the MEMS dies and to the control units in the device wafer 100 and have electrical contacts at the second surface 100b of the device wafer 100.

The formation of the first and second conductive plugs 310, 320 may be accomplished using any suitable process well known in the art. As an example, first of all, first through holes and second through holes may be formed in the device wafer 100 by photolithography and etching processes. In particular, each first through hole may extend through part of the device wafer 100 so that an electrical connection terminal of a respective one of the control units is exposed from the second surface 100b. Each second through hole may extend through both the device wafer 100 and the bonding layer 500 so that the contact pad of a respective one of the MEMS dies is exposed from the second surface 100b. Preferably, each of the first and second through holes extends through an isolation structure 102 in the device wafer 100 in order to minimize or prevent any adverse impact on the control units. Subsequently, a conductive material may be filled in the first and second through holes using a process well known in the art, such as physical vapor deposition (PVD), chemical vapor deposition (CVD) or electroplating, resulting in the formation of the first and second conductive plugs 310, 320. In this embodiment, the conductive material may be selected as a metal or alloy containing cobalt, molybdenum, aluminum, copper, tungsten or the like, or as a metal silicide (e.g., titanium silicide, tungsten silicide, cobalt silicide, or the like), a metal nitride (e.g., titanium nitride), doped polysilicon, or the like. However, the formation of the first and second conductive plugs 310, 320 is not limited to being accomplished by the above-described method because, for example, in another embodiment, the first conductive plugs 310 may be first formed by forming the first through holes and filling a conductive material therein, and the second conductive plug 320 may be then formed by forming the second through holes and filling a conductive material therein. Further, following the formation of the first and second conductive plugs 310, 320, the conductive material covering the second surface 100b may be removed using a CMP process.

FIG. 6 is a schematic cross-sectional view showing a structure resulting from the formation of rewiring layers in the method for fabricating the MEMS package structure in accordance with an embodiment of the present invention. Referring to FIG. 6, in a fourth step, the rewiring layers 400 electrically connected to the interconnection structures 300 are formed on the surface of the device wafer 100 opposing the first surface 100a (i.e., the second surface 100b of the device wafer 100 in this embodiment).

Specifically, the rewiring layers 400 may cover the second dielectric layer 104 and come into contact and thus electrical connection with the first and second conductive plugs 310, 320. For example, the formation of the rewiring layers 400 may involve depositing a metal layer over the second surface 100b of the device wafer 100 using a physical vapor deposition (PVD), atomic layer deposition (ALD) or chemical vapor deposition (CVD) process and then patterning the metal layer. The rewiring layers 400 may be formed either of the same material as the first or second conductive plug 310, 320 or of a different material.

Each rewiring layer 400 may include a rewiring connection and a solder pad electrically connected to the rewiring connection. The rewiring connection may be electrically connected to an interconnection structure 300 so that an electrical connection of the MEMS die and the device wafer 100 is lead out to the side of the device wafer away from the MEMS die. The solder pads electrically connected to the rewiring connections may be configured to connect the rewiring layers 400 to external signals or devices for processing or controlling electrical signals received from the rewiring connections.

With the above-described method for fabricating MEMS package structure, the MEMS die is bonded to the first surface 100a of the device wafer 100 and the interconnection structure 300 that is electrically connected to both the contact pad of the MEMS die and the control unit in the device wafer 100 is formed in the device wafer 100, with the rewiring layer 400 being arranged on the surface of the device wafer 100 opposing the first surface 100a. Arranging the rewiring layer and the MEMS die on opposing sides of the device wafer is conducive to shrinkage of the MEMS package structure. In addition, the MEMS package structure allows the integration of a plurality of MEMS dies of the same or different functions (or uses) and structures on the same device wafer. This is helpful in addressing the requirements of practical applications in terms of integration, portability and performance of MEMS package structures containing MEMS dies.

Described above are merely several preferred embodiments of the present invention, which are not intended to limit the present invention in any sense. In light of the principles and teachings hereinabove, any person of skill in the art may make various possible variations and changes to the disclosed embodiments, without departing from the scope of the invention. Accordingly, any and all such simple variations, equivalent alternatives and modifications made to the foregoing embodiments without departing from the scope of the invention are intended to fall within the scope thereof.

The provided MEMS package structure includes a MEMS die and a device wafer. The MEMS die includes a closed micro-cavity and a contact pad for being coupled to an external electrical signal. The device wafer has a first surface and a second surface opposite to the first surface, and the MEMS die is arranged on the first surface. In the device wafer, there is arranged an interconnection structure electrically connected to each of the contact pad and the control unit. On the second surface of the device wafer, there is arranged a rewiring layer electrically connected to the interconnection structure. This MEMS package structure achieves an electrical connection of the MEMS die and the device wafer, and with a reduced package structure sized by arranging the MEMS die and the rewiring layer on opposing sides of the device wafer. In addition to size shrinkage, the MEMS package structure is also improved in terms of function integration ability because a plurality of MEMS dies of the same or different functions and structures are allowed to be integrated therein.

With the provided method, the MEMS die is bonded to the first surface of the device wafer and the interconnection structure that is electrically connected to each of the contact pad of the MEMS die and the control unit in the device wafer is formed in the device wafer, with the rewiring layer being arranged on the surface of the device wafer opposing the first surface. Arranging the MEMS die and the rewiring layer on opposing sides of the device wafer is conducive to shrinkage of the MEMS package structure. In addition to size shrinkage, the MEMS package structure is also improved in terms of function integration ability because a plurality of MEMS dies of the same or different functions and structures are allowed to be integrated therein.

What is claimed is:

1. A micro-electro-mechanical system (MEMS) package structure, comprising:
a MEMS die comprising a closed micro-cavity and a contact pad configured to be coupled to an external electrical signal;
a device wafer having a first surface and a second surface opposite to the first surface, wherein the MEMS die is bonded to the first surface, and wherein a control unit associated with the MEMS die is arranged in the device wafer;
an interconnection structure arranged in the device wafer, wherein the interconnection structure is electrically connected to each of the contact pad and the control unit; and
a rewiring layer arranged on the second surface, wherein the rewiring layer is electrically connected to the interconnection structure.

2. The MEMS package structure of claim 1, wherein a plurality of MEMS dies are arranged on the first surface, and wherein the plurality of MEMS dies are categorized in a same or different types depending on a fabrication process thereof.

3. The MEMS package structure of claim 1, wherein a plurality of MEMS dies are arranged on the first surface, and wherein the plurality of MEMS dies are categorized in a same or different types depending on a vacuum level of the micro-cavity thereof.

4. The MEMS package structure of claim 1, wherein a plurality of MEMS dies are arranged on the first surface, and wherein the plurality of MEMS dies include at least one of: a gyroscope, an accelerometer, an inertial sensor, a pressure sensor, a displacement sensor and a micro-actuator.

5. The MEMS package structure of claim 1, wherein the control unit comprises one or more MOS transistors.

6. The MEMS package structure of claim 5, wherein the interconnection structure comprises
a first conductive plug and a second conductive plug, wherein: the first conductive plug extends through at least a part of the device wafer and is electrically connected to the control unit; and the second conductive plug extends through the device wafer and is electrically connected to the contact pad, and wherein the rewiring layer is electrically connected to each of the first and second conductive plugs.

7. The MEMS package structure of claim 6, wherein an isolation structure is arranged in the device wafer and located between adjacent MOS transistors, and wherein each of the first and second conductive plugs extends through the corresponding isolation structure.

8. The MEMS package structure of claim 1, further comprising:
a bonding layer covering the first surface, wherein the MEMS die is bonded to the first surface by the bonding layer; and
an encapsulation layer covering the MEMS die and the bonding layer.

9. The MEMS package structure of claim 8, wherein the bonding layer comprises an adhesive material.

10. The MEMS package structure of claim 9, wherein the adhesive material comprises a dry film.

11. The MEMS package structure of claim 1, wherein the micro-cavity is filled with a damping gas or is vacuumed.

12. The MEMS package structure of claim 1, wherein the rewiring layer comprises a rewiring connection, and wherein a solder pad is electrically connected to the rewiring connection.

13. A method for fabricating a micro-electro-mechanical system (MEMS) package structure, comprising:
providing a MEMS die and a device wafer for control of the MEMS die, wherein: the MEMS die comprises a closed micro-cavity and a contact pad configured to be coupled to an external electrical signal; the device wafer has a first surface; and a control unit is formed in the device wafer;
bonding the MEMS die to the first surface;
forming an interconnection structure in the device wafer, wherein the interconnection structure is electrically connected to each of the contact pad and the control unit; and
forming a rewiring layer on a surface of the device wafer opposing the first surface, wherein the rewiring layer is electrically connected to the interconnection structure.

14. The method for fabricating a MEMS package structure of claim 13, wherein bonding the MEMS die to the first surface comprises:
forming a bonding layer to bond the MEMS die to the first surface; and
forming an encapsulation layer to cover the MEMS die and the bonding layer.

15. The method for fabricating a MEMS package structure of claim 13, wherein forming the interconnection structure in the device wafer comprises:
forming a first conductive plug and a second conductive plug in the device wafer, wherein: the first conductive plug extends through at least a part of the device wafer and comes into electrical connection with the control unit; and the second conductive plug extends through the device wafer and comes into electrical connection with the contact pad, and wherein each of the first and second conductive plugs has one end exposed at the surface of the device wafer opposing the first surface.

16. The method for fabricating a MEMS package structure of claim 13, further comprising, prior to the formation of the interconnection structure in the device wafer,
grinding the device wafer along a thickness direction of the device wafer from a side of the device wafer opposing the first surface.
